(19) United States
(12) Patent Application Publication
(10) Pub. No.: US 2020/0379010 A1
(43) Pub. Date: Dec. 3, 2020

(54) SYSTEMS AND METHODS FOR HIGH SPEED TEST PROBING OF DENSELY PACKAGED SEMICONDUCTOR DEVICES

(71) Applicant: ESSAI, INC., Fremont, CA (US)

(72) Inventors: Joven R. Tienzo, Fremont, CA (US); Hin Lum Lee, Fremont, CA (US); Joe Xiao, Union City, CA (US); Chee Wah Ho, Fremont, CA (US); Nasser J. Barabi, Lafayette, CA (US)

(21) Appl. No.: 16/884,998

(22) Filed: May 27, 2020

Related U.S. Application Data
(60) Provisional application No. 62/854,117, filed on May 29, 2019.

(51) Int. Cl. G01R 1/067; G01R 1/073; G01R 31/27; G01R 31/26

(52) U.S. Cl. CPC G01R 1/06772; G01R 31/2601; G01R 31/27; G01R 1/07307

(57) ABSTRACT

The present invention relates to systems and methods that enable a connection to be made to a high speed, packaged or unpackaged semiconductor device that preserves signal integrity using probes that exhibit the properties of a coaxial transmission line so as to provide an accurate representation of the environment in which the device under test will be used. The coaxial structure further reduces capacitive coupling between probes resulting in significantly improved crosstalk performance.

### CROSS REFERENCE TO RELATED APPLICATION

This non-provisional application claims priority to U.S. Provisional Application No. 62/854,117, Attorney Docket No. ES-1901-P, filed on May 29, 2019, of the same title, by inventors Joven R. Tienzo et al., which is incorporated herein by reference.

### BACKGROUND

The present invention relates to systems and methods for high speed test probing of densely packaged semiconductor devices.

The methods and devices described herein are used to preserve signal integrity in a test environment for packaged semiconductor devices that accurately replicates the conditions that the device will experience in a designed application. To this end, the test fixture should provide the signal with transmission and termination characteristics that are predictable over the intended frequency range and match the performance specifications for the semiconductor part. The shielding performance of coaxial structures offers greatly improved crosstalk performance because the inter-probe coupling is substantially eliminated, being little more than that inherent in the device-under-test (DUT).

Simple testers that are used to verify the functionality of semiconductor components such as microprocessors Q and logic gate arrays generally make direct connection to the part and both inject and monitor voltages at connection points in a systematic manner. In general, the speed at which the tests are carried out can be increased until testing becomes unreliable and this frequency of operation set as the maximum test frequency. However, modern devices are designed to operate at very high speeds and unless the devices can be tested at their design operating speeds, any test quickly becomes inadequate and less representative of actual device capability. Typical a direct connection system can be used for a few hundreds of megahertz (MHz) providing the lengths of the connecting wires are kept short. Once the wire lengths approach fractions of a wavelength, then the operating conditions of the part under test become less certain because of impedance transformations that occur and phase shifts that are implicit in any time delays that are introduced.

By way of illustration, consider a part under test that is operating at a switching speed (clock speed, for example) of 30 MHz, this corresponds to a wavelength in free space of about 10 meters, and essentially the same in air. The time delay introduced when a wire is connected to link a signal from the device-under-test to a measuring appliance is in the neighborhood of about 1 nano-second per foot of wire, or about 33 pico-seconds per centimeter. So it can be seen that using short wires in the neighborhood of an inch or so (2.5 cm) introduces a time delay of close to 80 ps and corresponds to 2.5/1000, or 0.0025λ (a quarter of a percent of a wavelength). If the clock frequency is increased to 300 MHz, this same inch of wire represents 2.5 percent of a wavelength and at 3 GHz (now commonplace amongst high performance microprocessor parts) is a quarter of a wavelength, which can introduce disastrous errors into the measuring system; in this quarter wave case, a high impedance at one end of the connection, such as the input impedance of an amplifier, is transformed to a very low impedance close to a short circuit at the other end, where the device under test might be connected and conversely for a low impedance termination. Therefore high speed testing requires a sophisticated approach to connections for signals and a technical solution that is more complicated than has been used previously.

It is therefore apparent that an urgent need exists for testing methods and equipment that allows full performance evaluation conditions to be provided to the device under test. This improved test probe system enables realistic device assessment over the performance range specified by the device manufacturer without constraint due to the test equipment changing the working conditions of the device under test.

### SUMMARY

To achieve the foregoing and in accordance with the present invention, systems and methods for high speed test probing of densely packaged semiconductor devices is provided. In particular the systems and methods for connections to be made to a packaged semiconductor part, a probe assembly comprised of several connection points can be used. In general, the semiconductor package will only be approximately flat and so it is important that the probes are able to make reliable connections to a package that is not at a uniform distance. Conventionally, spring probes are used that enable compliance over quite a range of flatness parameters whilst ensuring sufficient pressure to make positive contact despite oxidation or similar contamination of the contact surface on the device under test.

Of particular interest are larger semiconductor packages having very high contact density. Typically, these will be in the form of either a BGA (Ball Grid Array) or LGA (Land Grid Array) where the contacts are located on the base of the semiconductor package and either finished with, for example, a solder ball in the case of the BGA or simply solder-free contact lands in the case of an LGA. As operating frequencies increase, the physical distance to connection points begins to play an increasingly important part in limiting the speed of operation of the device itself so a minimum distance design should be employed to overcome, or at least constrain this problem. Equally, coupling between probe elements due to either capacitive or inductive effects seen as “cross-talk” is an undesirable error source and this too should be considered and minimized. Except for the peripheral balls or lands that are the contact points for the device-under-test, each is surrounded by eight other connection points in the array so, if a probe is attached for test purposes, then there will be coupling between any connection and its eight neighbors as a result of parasitic capacitance or the mutual inductance between the probe elements, or pins. Primarily, because the effect of this capacitance at the higher test frequencies, this displaying an impedance that is inversely related to frequency, the speed limit of the device under test becomes dominated by the propriety of connections that link it to other components. A test probe, by definition, is a temporary connection and so carries the burden of having to be robust in order for it to be useful for many test cycles. This aspect alone translates into a structure that is prone to both capacitive and inductive coupling between neighboring connections since the test pins in the probe assembly are necessarily closely spaced and run parallel for several millimeters, sometimes as much as a centimeter or more depending on the testing environment. Once outside the test probe structure itself, shielded cabling is generally used, which limits the addition of parasitic coupling, but at the cost of relatively expensive interconnection wiring to the test instruments being used for the tests.

By locating the pins, that form the connection to the device under test, within a metal body that surrounds each pin, the inter-pin parasitic effects can be controlled and minimized. In addition, if suitable dimensions are selected, the characteristic impedance of the assembly can be determined and controlled so that problems related to mismatching of drive impedances can also be resolved and the device under test inspected up to its design operating frequencies.

Note that the various features of the present invention described above may be practiced alone or in combination. These and other features of the present invention will be described in more detail below in the detailed description of the invention and in conjunction with the following figures.

### BRIEF DESCRIPTION OF THE DRAWINGS

In order that the present invention may be more clearly ascertained, some embodiments will now be described, by way of example, with reference to the accompanying drawings, in which:

FIG. 1A illustrates a simplified cross-sectional view of one embodiment of the present invention with the probe assembly in the contact position;

FIG. 1B shows the relaxed or resting position of the embodiment of FIG. 1A;

FIG. 2 is a simplified perspective depiction of the probe in the relaxed or resting position;

FIG. 3A illustrates a Ball Grid Array;

FIG. 3B shows a Land Grid Array;

FIG. 4A shows a representative spring pin; and

FIG. 4B illustrates the contact of the pin with a BGA ball and shows the detail of the insulating components.

### DETAILED DESCRIPTION

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow.

Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “always,” “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary.

The present invention relates to systems and methods for a high speed test probe intended for inspection of densely packaged semiconductor devices. Although it should be clear that this technology can be down-scaled for small semiconductor packages, the current area of interest focuses upon packaged semiconductor devices having high connection counts and are typically seen as BGA and LGA structures. Other technologies that present the connection points directly on the semiconductor, such as Flip-Chip, are of course very similar and the use of the descriptor BGA or LGA is not intended to be limiting. Pin Grid arrays are also appropriate connection technologies.

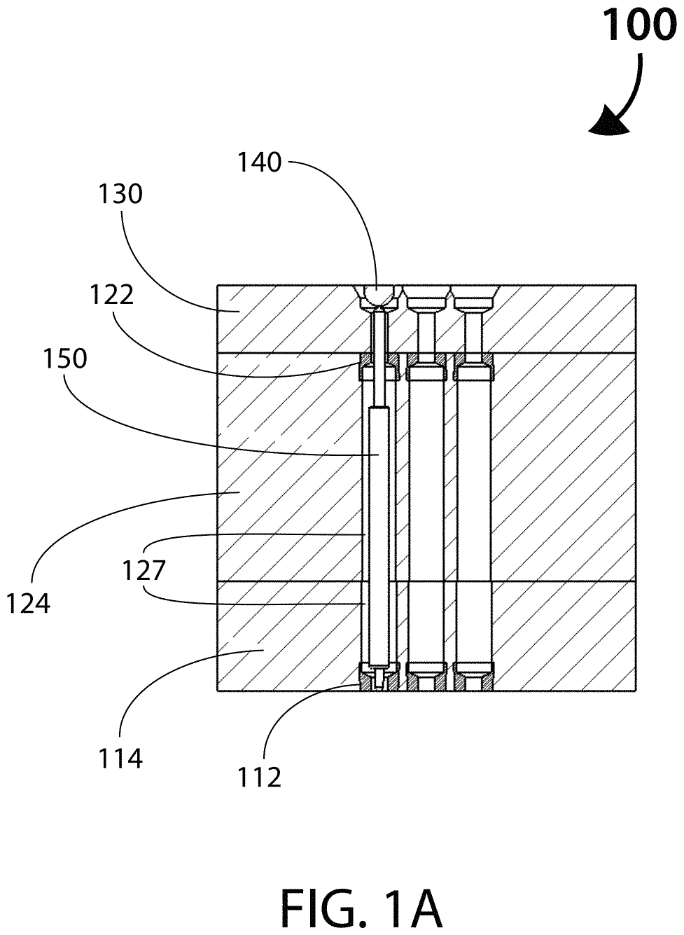

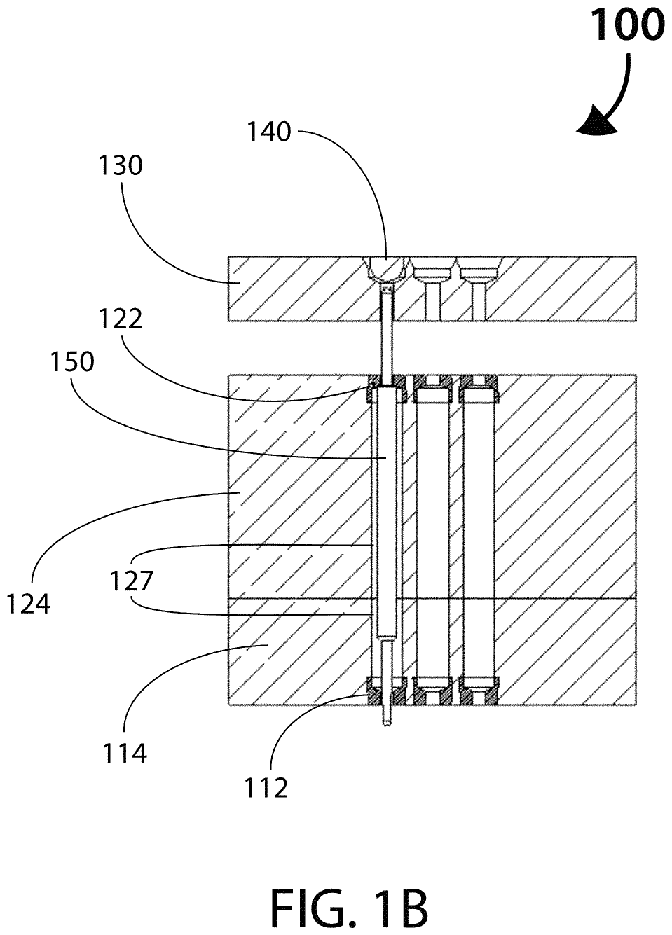

To facilitate discussion, FIG. 1A shows a simplified cross-section of an exemplary probe 100 with three connecting pins. Probe 100 is shown in the operational position with the contact pin assembly 150 compressed and in contact with a ball 140 of a Ball Grid Array. The pin assembly 150 has a major diameter which is typically in the neighborhood of a fifth of a millimeter in a high density probe and is located in a channel 127 that is drilled in the upper and lower housing elements 124 and 114 respectively as required. Connection from the testing instruments is made to the pin 150 at the outer surface of the lower housing 114. The connection to the test equipment is not shown in this figure, but is established by placing a printed circuit board securely against the bottom edge of the probe so that the lower end of the contact pin assembly is pushed firmly against mating lands on the circuit board, from whence these connections may be routed to suitable interconnection points such as coaxial sockets or multi-pin connectors located on the circuit board. In one embodiment, the circuit board element is secured to the bottom of the probe assembly using screws and a clamping plate that ensures that there can be no relative motion between the probe assembly and the circuit board. The pin 150 is retained radially at the lower end by an insulator 112 made of a material that is mechanically stable such as a “tooling plastic.” Examples of one such material is UHMW-PE (Ultra High Molecular Weight Polyethylene) or Nylon with the requirement that the selected material exhibit good temperature properties, toughness and abrasion resistance. Persons skilled in the art can appreciate that mechanical stability is important in the material used and it is beneficial if the selected material is easily characterized electrically having suitable dielectric constant across the frequency ranges anticipated in use. This insulator 112 is installed into, or fabricated within, a machined space at the outer surface of the lower housing 114 and may be fabricated in any of a number of ways.

Housing elements 124 and 114 may be made of any suitable conductive material, and in one embodiment an aluminum alloy 6061 is used; and for robustness, with a T6 temper. Channel 127 is drilled in both the upper housing 124 and in the lower housing 114 so that, when assembled, the channels in both of these elements are accurately aligned. In the same way as insulating material 112 is provided, terminating at the lower (outer) surface of lower element 114, a similar insulating component 122 is provided, terminating at the upper surface of the upper element 124 and it should be noted that the illustrated dimensions for 124 and 114 are only for example, in that they can be sized for height in any way that lends itself to ease of manufacture and assembly of the structure. An upper component 130 is shown in this example for a BGA probe. This component provides a surface feature that guides each solder ball 140 to which a connection is desired so that it is held in a stable manner as the connecting pin is compressed.

Component 130 may be made of an insulating material if it is very thin, but if there is significant thickness to the part, it may be made of metal and plated with an insulating lining where the connecting pin penetrates it to mate with the ball 140. In one embodiment this component 130 is made from 6061 aluminum and is passivated by anodizing the selected surfaces. Typically the outer surfaces and the holes are anodized and the surface that butts up against the upper housing 124 can be left untreated, although even if the entire part is anodized, capacitive coupling is sufficient to assure that it is effectively connected to the housing at higher frequencies. In some embodiments, an insulating sleeve may be created and positioned within this component; this has the advantage that, at the cost of some complexity in manufacturing, a predetermined impedance for the coaxial structure so formed may be established so that discontinuities are minimized and in consequence any frequency dependence can be controlled.

If a goal is to minimize crosstalk, that undesired coupling of neighboring signals to a desired signal, then the shielding effect of the metal enclosure is sufficient. In one embodiment the pin density is very high, the major diameter of a connecting pin assembly is 0.17 mm and the diameter of the hole through which this part of the connecting pin passes is about 0.2 mm. Using the coaxial cable formula Z₀={138 Log₁₀ (D/d)}/√εᵣ where Z₀ is the characteristic impedance, D is the diameter of the channel and d is the major diameter of the pin (Fr is the relative dielectric constant which is about 1 for air making the equation simpler) we see that this is about 10Ω. To make a 50Ω section using this same pin, we need to make the channel about 2.3 times the pin diameter. Fortunately it is rarely necessary to make every section a 50Ω section and since every test jig is usually specific to the tested part this is not inconvenient. It is also possible to compensate for anomalies at specific frequencies by test-specific tuning; for example the addition of a dielectric sleeve can be used to reduce the characteristic impedance of the transmission line structure formed by the connection pin assembly and the housing.

Turning now to FIG. 1B the probe is shown in the open, or relaxed position. In this position, the pin assembly 150 is expanded under spring pressure and the combined effect is to cause the upper component 130 to rise from the pin housing 124; there is almost always enough friction due to the extremely close tolerances of machining between the pin and the drilling that it penetrates in the upper component 130 that it will raise, and it is rare that the probe reaches a wear point in its service lifetime where the pins are sufficiently loosened in this fit that they move independently of the upper component. If one contrasts FIG. 1B against FIG. 1A, it can be seen that the upper pin is fixed with the main body of the pin assembly 150 whilst the lower pin is stationary in one of two positions relative to the lower housing 114. Movement of the pin assembly is limited along the symmetrical axis of the pin assembly to that allowed by the position of the insulating elements 112 and 122 in the lower and upper housings respectively. When an interconnection circuit board, that allows connection to be made to the peripheral testing equipment, is present then the lower pin is pushed up so that it is flush with the bottom edge of the lower housing 114. Spring pressure holds the pin firmly in contact with an interconnection circuit board so positioned and suitable choice of plating ensures a consistent connection. In an alternative embodiment the lower pin is accommodated by matching, plated through vias in an interconnection circuit board and soldered in place.

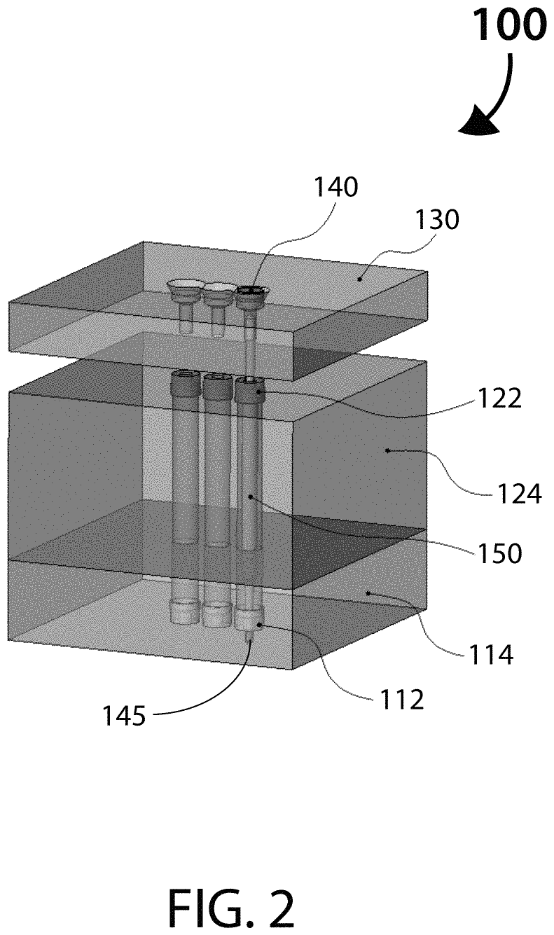

FIG. 2 is a perspective view of this exemplary, three-pin test probe. The figure shows the probe in the resting, or relaxed position that is shown in FIG. 1B where the upper component 130 is not firmly in contact with the upper housing component 124 as it would be in the testing position. Here, the connecting pin 150 displacement can be seen where the major diameter element is moved upwards, away from the lower insulator 112. The lower pin 145 is pressed firmly against the insulator by a spring located between this pin and the outer shell of the connecting pin assembly, which pushes them apart, although when the probe is fastened to its interconnection circuit board, the pin position is determined by the circuit board and so may be flush with the bottom of the lower housing. The small, but unavoidable amount of friction between the upper parts of the pins that penetrate component 130 helps that component to float away from the upper housing when the spring pressure extends the pin assembly so that the upper end of the outer shell pushes against the upper insulator 122.

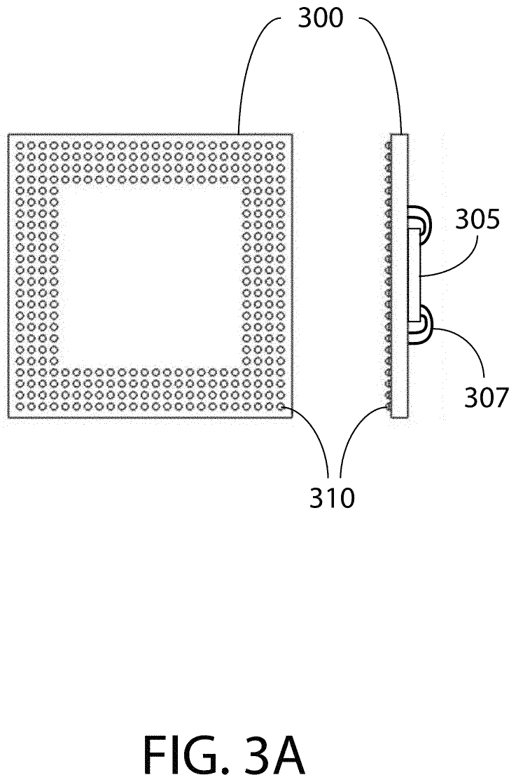

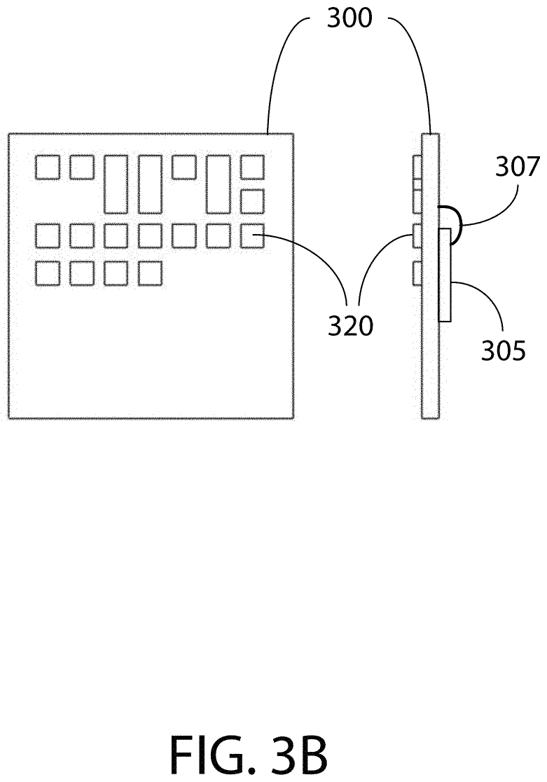

Turning now to FIG. 3A, a plan and edge view of a typical Ball Grid Array is shown. The array can be anything from a small number of connections to an array that covers the entire bottom of the semiconductor package. The substrate 300 can be of any suitable material but in applications where considerable power is dissipated this is often a ceramic, such as alumina or similar aluminum oxide materials, for example sapphire or ruby, with excellent thermal transfer properties. In high power applications Beryllium Oxide is found to be a suitable material having excellent thermal transfer properties. The semiconductor part 305 is generally located on the other side from the contact regions of the BGA and connected by bonding it with wires 307 to bonding pads that are connected through the ceramic to the BGA using vias that are through-plated. It is not uncommon to find traces that interconnect vias and BGA points run between the pads upon which the contact balls of the BGA are formed. Each of these BGA pads is typically built up with a ball 310 of a solder material of approximately hemispherical shape. The probe is specific to a particular package and allows these solder balls of the grid array to nest into depressions that secure them in position as the connecting pin applies pressure to make contact.

In a similar way, FIG. 3B illustrates a Land Grid Array (LGA) where plain, planar contacts 320 are plated onto the package base but no solder is applied to form a ball; these lands that are the contacts to which a connection will be made are often a square or rectangular appearance but there does not have to be a prescribed geometry, as opposed to the BGA form, where a generally circular form for the pad aids the formation of a solder ball. Connection within the package is similar to that described above, with plated vias joining the two sides. This has the benefit that large land areas may be combined with smaller land areas which means that high current or low thermal resistance paths can be established independently of the geometry limits to which solder balls are constrained. In this case, where an LGA is being probed, the upper component 130 of the probe assembly becomes optional, since there is no mechanical structure that can be used to set the direction of the connection forces and the connecting pins 150 can be allowed to contact the lands directly. In some embodiments, a thin replaceable layer is used as a wear strip to reduce or limit damage to the probe housing after a large number of repeated applications. It should be noted that although reference is made to BGA and LGA connections, there are other connecting technologies that are available for semiconductor components, for example “Flip Chip” where contacts are made directly on the semiconductor material and may be plated or “bumped” so that the part may be inserted directly, unpackaged and without bonding wires; the probe technology described here is equally applicable to components that are un-mounted or unpackaged.

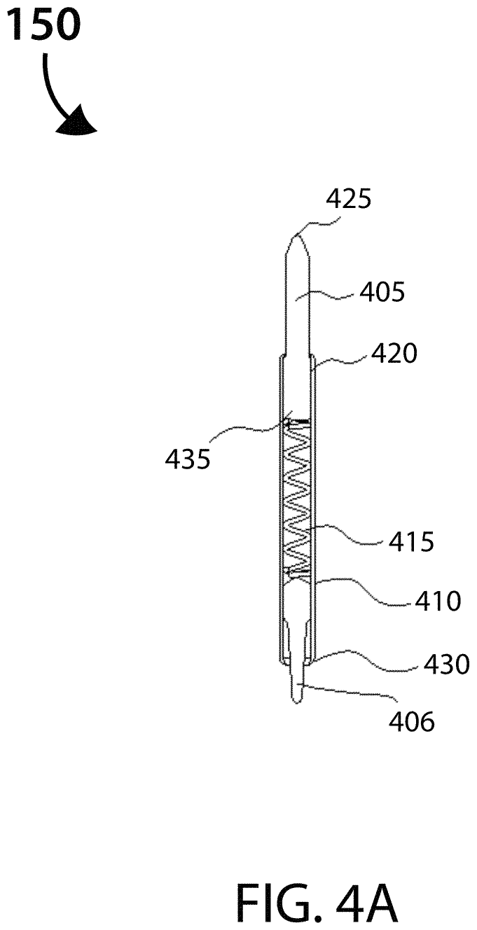

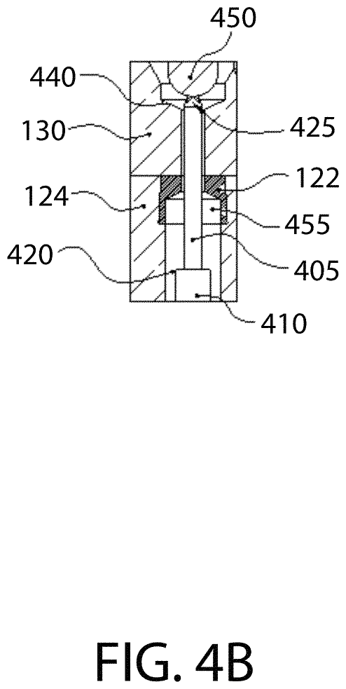

The pin 150 that is used to make the connection to the DUT is a compressible pin and can be fabricated in a number of ways to allow the pin to be made suitable for the particular application. FIG. 4A is an illustration of an example pin 150 and is designed to have long duty life as well as exhibiting considerable precision in its construction. Four parts are used in construction; two connecting pins 405 and 406, a retaining barrel or shell 410 and a spring 415. The pins 405 and 406 may be, conveniently, the same part in some applications but, depending upon particular equipment needs, this is not always the case. Differences are predominantly required at the contact point 425 that connects to the DUT, where it is necessary to have sufficient pressure or movement to guarantee that a good connection can be made even when there is contamination at the DUT; oxidation of one or more of the balls in a BGA is a common problem and so the tip 425 may be altered so as to yield a different geometry. In the illustration of FIG. 4A it can be seen that the inner end of the lower pin 406 has a conical shape which serves to center the spring 415 that helps to reduce friction with the barrel that would be present if a flat surface was used and the spring allowed to skew towards one edge. By contrast, the upper pin 405 is somewhat more massive to add to its strength so that it can endure repeated application of off-center forces that can occur when a ball in the BGA is imperfectly formed. Further, since it is intended to be crimped to the barrel to form a robust fixed assembly, it may be machined so as to favor this securing process. Note that there is no requirement to locate the spring centrally on-axis at this end since there is no movement relative to the barrel.

In some embodiments, the tip is segmented so that there are more than one contact point to pierce the oxide. In other embodiments, the tip is electrically machined so as to give a very rough surface with multiple points of contact. The tip 425 may be plated in the same material as the rest of the pin 405 or may have a preferred plating to reduce thermoelectric voltage effects. Persons of ordinary skill will understand that wear properties and plating choices may not be mutually compatible and that compromises will have to be made; for example a gold plating may be preferred for its corrosion resistance, yet a nickel plating chosen for its hard wearing properties.

The pins 405 themselves can be of any suitable material having the required mechanical properties and a plating material used to achieve the desired electrical properties. The opposite end of the pin 405 within the barrel has a shoulder 435, which is chosen to be a snug fit into the enclosing barrel 410, and forms the surface against which the spring 415 exerts force; there being two pins 405 and 406, the spring pushes them apart to the extent allowed by the geometry of the parts.

The illustration of FIG. 4A shows a neck 430 formed so as to have an inner diameter that matches the major diameter of pin 406 so pin 406 is placed into the barrel 410 followed by the spring 415 and then pin 405 is installed. Once this latter pin is positioned accurately in the barrel, a crimp 420 can be formed that secures the pin and the barrel into a fixed relationship and pin 406 can be compressed into the barrel to the extent allowed by the spring. The neck of the barrel 430 can be formed so as to give a good quality fit that ensures excellent conductivity. This is an important aspect for high frequency applications since the skin effect forces current flow on the outside of the barrel surface, predominantly.

FIG. 4B shows, by way of example of some embodiments, an enlarged view of the contact between a BGA ball 450 and a connecting-pin point 425. The pin is engaged under spring pressure and, being less malleable than the contact ball 450, pushes into it. This movement displaces any light oxide build up and makes a good electrical contact between the two parts. The upper layer 130 of the probe assembly 100 has a series of depressions 440 cut or formed into it so that the ball is held captive relative to the pin so that sideways motion is resisted and the risk of damaging the pin is reduced. The pin has to penetrate the housing 124 passing through it and so an insulating guide 122 may be present to prevent short circuits between the pin 405 and the upper housing 124 when the clearance is insufficient to guarantee that they do not touch. This guide can be created by cutting a pocket into the housing; in this example a conical or shouldered shape is first cut into the upper housing 124 and then a suitable material is forced into the pocket. This may be a plastic material pushed in under pressure, an insulating material in liquid form such as a resin which may then cure and harden so as to retain its shape. Once the material is ready to be machined, a pilot hole of the correct size to accept the pin 405 is drilled through the entire housing 124 and 114 and the insulator material 122 and then, coaxially with this, a larger hole drilled in the housing elements 124 and 114, which will allow the barrel assembly 410 to fit with sufficient clearance 127. In some embodiments, the insulation layer between the pin and the upper housing is formed by anodization of the aluminum upper housing 124 and there is no separate insulator provided; an anodization thickness between 5 μm and 15 μm has been found to be acceptable.

For completeness an exemplary crimp area 420 that secures this pin 405 into the barrel 410 is also shown. In some embodiments, a small flexible washer 455 may be installed to serve as a buffer between the harder pin assembly and the insulator 122 to reduce wear or damage to the insulator over time and repetitive cycles. The conical or shouldered section shape of the insulator is exemplary and it should be clear that so long as the insulator is secured in place relative to the housing 124 then other solutions may be used; for example any keyed surface that allows durable adhesion or restraint between the housing and the insulator material can be used. The flexible washer 455 serves only to absorb impact shock from the pin assembly and if the lifetime of the probe assembly is determined to be sufficient without this component then it may be excluded. In one embodiment, the diameter of the channel cut into the housing is about 0.2 mm and the pin barrel is about 0.17 mm. In another embodiment, the housing channel is 2.3 times the barrel diameter and a smaller pin assembly is used so that the coaxial section has a line impedance of 50Ω. In yet another embodiment, a dielectric sleeve is fitted that reduces the impedance of this transmission line section to a lower impedance whilst maintaining a required tolerance for its operating voltage. Dielectric sleeves may also be used to provide reactive elements to tune out or match the device under test to the driving impedance of the testing equipment.

It will be observed that the pin and barrel crimp 420 secures these two parts firmly together and this end of the pin assembly is used to make the connection to the DUT. This offers the benefit that any incidental side loading that has to be reacted by the neck 430 region at the other end of the pin assembly is far lower than if it were proximate to the contact point and this contributes significantly to good probe assembly lifetime.

The lower housing 114 also has an insulating section where the other, sliding pin 406 penetrates it. The connection between the pin assembly and the test equipment that is connected to the DUT by the probe assembly is connected at this point and unlike the assembly in FIG. 4B this pin does not move relative to the housing when in use, since an interconnection circuit board is positioned securely, relative to the lower housing as explained previously; it is held under pressure by the pin assembly spring 415 at all times and since the attached cables are supported by external structures, no repeating offset forces have to be reacted by the neck 430 so there is no asymmetric wear.

The probe assembly dimensions vary according to the application, the number of contacts to be connected and the flatness of the DUT. The probe height measured from the bottom of the lower housing 114 to the top surface of the upper housing is typically between 2 mm and 5 mm. The upper layer 130 construction is not fixed. It may be any material that can provide insulation or a combination of materials that can perform this function. If a passivated (anodized) aluminum is used, this has the advantage of continuing the shielding as close to the ball of a BGA DUT as is possible, but creates a parasitic capacitance to ground that should be considered when the test regime for the DUT is being designed. Specific applications may use a composite upper layer where the main bulk is anodized aluminum and specific connection points have a plastic insert to reduce this parasitic component whilst still retaining most of the shielding advantages.

In sum, the present invention provides a system and methods for high speed test probing of densely packaged semiconductor devices. The advantages of such a system include the ability to greatly reduce crosstalk between channels, which is exacerbated by very densely packed connection points.

While this invention has been described in terms of several embodiments, there are alterations, modifications, permutations, and substitute equivalents, which fall within the scope of this invention. Although sub-section titles have been provided to aid in the description of the invention, these titles are merely illustrative and are not intended to limit the scope of the present invention. In addition, where claim limitations have been identified, for example, by a numeral or letter, they are not intended to imply any specific sequence.

It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention.

What is claimed is:

1. A probe assembly for testing densely packaged semiconductor assemblies, the probe assembly comprising:
a housing machined with a plurality of channels to accept components so as to form a coaxial structure between each component and the housing;
a plurality of connecting pin assemblies, each pin assembly secured at one end and with a probing end free to move over a predetermined distance along the symmetrical axis of the assembly; and
insulating materials embedded into the housing to retain the plurality of connecting pin assemblies in one or more predetermined positions.

2. The assembly of claim 1 further comprising an insulating material with depressions to capture a ball of a BGA to prevent the probing end from skating on the surface of the ball.

3. The assembly of claim 1 further comprising an insulating material with depressions to capture the bumping feature of a flip-chip semiconductor to prevent the probe end from skating on the surface of the semiconductor.

4. The assembly of claim 3 wherein the insulating material alters the characteristic impedance of the co-axial structure.

5. The assembly of claim 1 wherein the channels in the housing are radiused to avoid an abrupt transition.

6. The assembly of claim 3 wherein the insulating material is formed by a layer of anodized aluminum created in the housing.

7. The assembly of claim 6 wherein the anodizing layer is between 5 μm and 15 μm thick.

8. The assembly of claim 1 wherein the channels in the housing that house any or all of the connecting pins are radiused to avoid uneven anodizing.

9. The assembly of claim 1 wherein a diameter of the channels is between 2 and 3 times diameter of the pin assembly, to minimize crosstalk between the more than one connecting pin assembly.

10. The assembly of claim 9 wherein the diameter of the channels is between 2.3 times a diameter of the pin assembly.

11. The assembly of claim 1 further comprising a flexible washer for buffering the pin assembly.

12. A probe assembly for testing densely packaged semiconductor assemblies, the probe assembly comprising:
an insulating plastic housing machined with a plurality of channels to accept components so as to form a coaxial structure between each component and the housing; and
a plurality of connecting pin assemblies, each pin assembly secured at one end and with a probing end free to move over a predetermined distance along the symmetrical axis of the assembly, and wherein the plastic housing is configured to retain the plurality of connecting pin assemblies in one or more predetermined positions.
